(19) United States
(12) Patent Application Publication
(10) Pub. No.: US 2026/0271443 A1
(43) Pub. Date: Sep. 10, 2026

(54) SEMICONDUCTOR CHIP, SEMICONDUCTOR DEVICE, AND METHOD FOR MANUFACTURING SEMICONDUCTOR DEVICE

(71) Applicant: InnoLux Corporation, Miao-Li County (TW)

(72) Inventors: Pei-Hsien LIU, Miao-Li County (TW); Chi-Han HSIEH, Miao-Li County (TW); Chiung-Chieh KUO, Miao-Li County (TW); Kuan-Hung KUO, Miao-Li County (TW)

(21) Appl. No.: 19/532,194

(22) Filed: Feb. 6, 2026

(30) Foreign Application Priority Data
Mar. 6, 2025 (CN) 202510260248.X

(51) Int. Cl. H10H 20/853; H10H 20/856; H10H 29/03

(52) U.S. Cl. CPC H10H 20/853; H10H 20/856; H10H 29/03

(57) ABSTRACT

A semiconductor chip includes a semiconductor unit, a pillar, a first electrode and a second electrode. The semiconductor unit includes a semiconductor die and a filler layer, wherein the filler layer surrounds the semiconductor die, and the semiconductor die includes a first-type semiconductor layer and a second-type semiconductor layer. The pillar is disposed on a first side of the semiconductor unit. The first electrode is electrically connected to the first-type semiconductor layer. The second electrode is electrically connected to the second-type semiconductor layer. The first electrode and the second electrode are disposed on a second side of the semiconductor unit, and center of gravity of the semiconductor chip is closer to the second side than to the first side.

### CROSS-REFERENCE TO RELATED APPLICATIONS

This application claims the benefits of the Chinese Patent Application Serial Number 202510260248.X, filed on March 6, 2025, the subject matter of which is incorporated herein by reference.

### BACKGROUND

### Field of the Disclosure

The present disclosure relates to a semiconductor chip, a semiconductor device, and a method for manufacturing a semiconductor device, and more particularly to a technique for forming a semiconductor device by placing a semiconductor chip on a substrate.

### Description of Related Art

Semiconductor chips have to be placed on a substrate to form semiconductor devices. Currently, fluid assembly methods are used to facilitate the assembly of semiconductor chips into designated positions on the substrate. However, due to the shape of the semiconductor chip, fluid assembly often suffers from poor fluid transfer yield, thereby reducing the assembly quality.

Therefore, it is desired to provide an improved semiconductor chip, semiconductor device and method for manufacturing a semiconductor device to alleviate and/or obviate the above problems.

### SUMMARY

The present disclosure provides a semiconductor chip, which comprises: a semiconductor unit including a semiconductor die and a filler layer, wherein the filler layer surrounds the semiconductor die, and the semiconductor die includes a first-type semiconductor layer and a second-type semiconductor layer; a pillar disposed on a first side of the semiconductor unit; a first electrode electrically connected to the first-type semiconductor layer; and a second electrode electrically connected to the second-type semiconductor layer, wherein the first electrode and the second electrode are disposed on a second side of the semiconductor unit, and a center of gravity of the semiconductor chip is closer to the second side of the semiconductor unit than to the first side of the semiconductor unit.

The present disclosure further provides a semiconductor device, which comprises: a substrate including a pad; a unit definition layer disposed on the substrate and provided with a receiving hole, wherein the pad is disposed in the receiving hole ; and a semiconductor chip disposed in the receiving hole and bonded to the pad, comprising: a semiconductor unit including a semiconductor die and a filler layer, wherein the filler layer surrounds the semiconductor die, and the semiconductor die includes a first-type semiconductor layer and a second-type semiconductor layer; a first electrode electrically connected to the first-type semiconductor layer; and a second electrode electrically connected to the second-type semiconductor layer, wherein the semiconductor unit has a first side and a second side, the first electrode and the second electrode are disposed on the second side of the semiconductor unit, and a center of gravity of the semiconductor chip is closer to the second side of the semiconductor unit than to the first side of the semiconductor unit.

The present disclosure further provides a method for manufacturing a semiconductor device, which comprises the steps of: providing a unit definition layer, wherein the unit definition layer includes a receiving hole; providing a semiconductor chip, wherein the semiconductor chip includes: a semiconductor unit including a semiconductor die and a filler layer surrounding the semiconductor die; a pillar disposed on a first side of the semiconductor unit; and an electrode electrically connected to the semiconductor unit and disposed on a second side of the semiconductor unit, wherein a center of gravity of the semiconductor chip is closer to the second side of the semiconductor unit than to the first side of the semiconductor unit; and disposing the semiconductor chip in the receiving hole in a fluid assembly manner.

Other novel features of the disclosure will become more apparent from the following detailed description when taken in conjunction with the accompanying drawings.

### BRIEF DESCRIPTION OF DRAWINGS

FIG. 1A is a schematic diagram of a semiconductor chip 1 according to an embodiment of the present disclosure;

FIG. 1B is a cross-sectional view corresponding to the cross-sectional line in FIG. 1A;

FIG. 2 is a schematic diagram of the manufacturing process of the semiconductor unit according to an embodiment of the present disclosure;

FIG. 3 is a schematic diagram of a semiconductor chip used for fluid assembly according to one embodiment of the present disclosure;

FIG. 4A is a schematic diagram of a semiconductor device (assembly process) according to one embodiment of the present disclosure;

FIG. 4B is a schematic diagram of a semiconductor device (assembly completed) according to another embodiment of the present disclosure; and

FIG. 5 is a flowchart illustrating the steps of the method for manufacturing a semiconductor device according to an embodiment of the present disclosure.

### DETAILED DESCRIPTION OF EMBODIMENTS

Reference will now be made in detail to exemplary embodiments of the present disclosure, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present disclosure does not intend to distinguish between components that have the same function but have different names. In the following description and claims, words such as “containing” and “comprising” are open-ended words, and should be interpreted as meaning “including but not limited to”.

The terms, such as “about”, “substantially”, or “approximately” are generally interpreted as within 10% of a given value or range, or as within 5%, 3%, 2%, 1% or 0.5% of a given value or range.

In the specification and claims, unless otherwise specified, ordinal numbers, such as “first” and “second”, used herein are intended to distinguish components rather than disclose explicitly or implicitly that names of the components bear the wording of the ordinal numbers. The ordinal numbers do not imply what order a component and another component are in terms of space, time or steps of a manufacturing method. Thus, what is referred to as a “first component” in the specification may be referred to as a “second component” in the claims.

In the present disclosure, the terms "the given range is from the first numerical value to the second numerical value" and "the given range falls within the range from the first numerical value to the second numerical value" mean that the given range includes the first numerical value, the second numerical value, and other numerical values therebetween.

In addition, the semiconductor device of the present disclosure may be used in electronic devices, and the electronic devices may include display devices, automation equipment, clamping devices, computing devices, mechanical equipment, drug dispensing equipment, exposure devices, printing devices, three-dimensional printing devices, automotive devices, imaging devices, assembly devices, backlight devices, antenna devices, tiled devices, touch electronic devices, curved electronic devices, or free shape electronic devices, but not limited thereto. The display device may, for example, include liquid crystal, light emitting diodes, fluorescence, phosphor, other suitable display media, or a combination thereof, but not limited thereto. The display device may be a non-self-luminous display device or a self-luminous display device. The antenna device may be a liquid crystal antenna device or a non-liquid crystal antenna device, and the sensing device may be a sensing device that senses capacitance, light, heat, or ultrasound, but not limited thereto. The tiled device may, for example, include a display tiled device or an antenna tiled device, but not limited thereto. It should be noted that the electronic device may be any of the aforementioned arrangements and combinations, but not limited thereto. Furthermore, the electronic device may be bendable or flexible. It should be noted that the electronic device may be any of the aforementioned arrangements and combinations, but not limited thereto. Furthermore, the electronic device may have a rectangular, circular, polygonal shape, a shape with curved edges, or other suitable shape. The electronic device may include peripheral systems such as a drive system, a control system, a light source system, a shelving system, etc. to support the display device, antenna device, or tiled device.

It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way, unless there is a special definition in the embodiment of the present disclosure.

In addition, the term "adjacent" or "neighboring" in the specification and claims is used to describe mutual proximity, and does not necessarily mean mutual contact.

In addition, the descriptions such as "when" or "during" in the present disclosure represent aspects such as "now, before or after", and are not limited to situations that occur at the same time, which is described first here. In the present disclosure, similar descriptions such as “arranged on” refer to the corresponding positional relationship between the two components, and do not limit whether there is contact between the two components, unless otherwise specified, which is described here first. Furthermore, when the present disclosure discloses multiple functions, if the word "or" is used between the functions, it means that the functions may exist independently, but it does not exclude that multiple functions may exist simultaneously.

The semiconductor chip of the present disclosure has a special structure that, compared to prior techniques, is more suitable for assembly to a desired position on a substrate using a fluid assembly method so as to form a semiconductor device. The structure of the semiconductor chip will be described first. Furthermore, for clarity, the directions in the drawings will be defined as X, Y and Z directions.

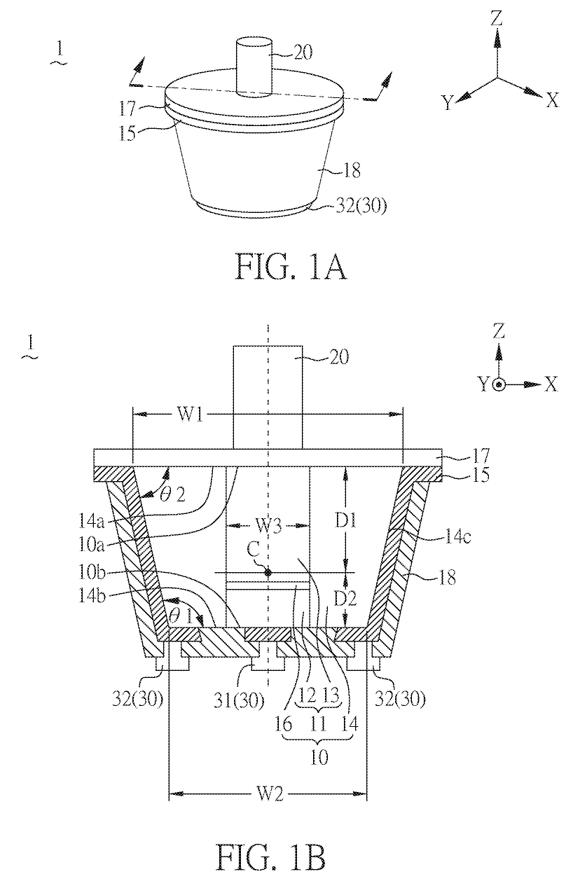

FIG. 1A is a schematic diagram of a semiconductor chip 1 according to an embodiment of the present disclosure, and FIG. 1B is a cross-sectional view corresponding to the cross-sectional line in FIG. 1A. As shown in FIGS. 1A and 1B, the semiconductor chip 1 includes a semiconductor unit 10, a pillar 20, a first electrode 31 and a second electrode 32. The semiconductor unit 10 includes a semiconductor die 11 and a filler layer 14, wherein the filler layer 14 surrounds the semiconductor die 11, and the semiconductor die 11 includes a first-type semiconductor layer 12 and a second-type semiconductor layer 13. The semiconductor unit 10 has a first side 10a and a second side 10b opposite to each other in the Z direction. The first-type semiconductor layer 12 may be adjacent to the second side 10b, and the second-type semiconductor layer 13 may be adjacent to the first side 10a, but it is not limited thereto. The pillar 20 is disposed on the first side 10a of the semiconductor unit 10. The first electrode 31 is electrically connected to the first-type semiconductor layer 12. The second electrode 32 is electrically connected to the second-type semiconductor layer 13. The first electrode 31 and the second electrode 32 are disposed on the second side 10b of the semiconductor unit 10. Furthermore, the semiconductor chip 1 may have a center of gravity C that is closer to the second side 10b of the semiconductor unit 10 than to the first side 10a of the semiconductor unit 10. For example, in the Z direction, the shortest distance between the center of gravity C and the first side 10a is defined as a first distance D1, and the shortest distance between the center of gravity C and the second side 10b is defined as a second distance D2, where the first distance D1 is greater than the second distance D2 (D1>D2).

In one embodiment, the filler layer 14 may have an upper surface 14a and a lower surface 14b opposite to each other in the Z direction, and the filler layer 14 may also have a side surface 14c for connecting the upper surface 14a and the lower surface 14b. In one embodiment, the semiconductor unit 10 may further include a reflective layer 15 disposed on the side surface 14c of the filler layer 14. The reflective layer 15 may be electrically connected to the second electrode 32. In one embodiment, a portion of the reflective layer 15 may also extend onto the lower surface 14b of the filler layer 14 and cover at least a portion of the lower surface 14b, but it is not limited thereto. In one embodiment, the semiconductor die 11 further includes an active layer 16 disposed between the first-type semiconductor layer 12 and the second-type semiconductor layer 13. In one embodiment, the semiconductor chip 1 may further include a conductive layer 17 electrically connected to the reflective layer 15 and the second-type semiconductor layer 13, and disposed on the first side 10a of the semiconductor unit 10. For example, in the Z direction, the conductive layer 17 may be disposed between the first side 10a of the semiconductor unit 10 and the pillar 20, but it is not limited thereto. In one embodiment, the semiconductor chip 1 may further include an insulating layer 18 disposed on the reflective layer 15. For example, the reflective layer 15 may be disposed between the filler layer 14 and the insulating layer 18, but it is not limited thereto. The details of the various components of the semiconductor chip 1 will be described in the following.

Regarding the semiconductor unit 10, in one embodiment, the type of the semiconductor unit 10 may include a light-emitting diode, but it is not limited thereto. The first-type semiconductor layer 12 and the second-type semiconductor layer 13 may correspond to different polarities of the light-emitting diode. For example, in some embodiments, the first-type semiconductor layer 12 may be a P-type semiconductor layer, and the second-type semiconductor layer 13 may be an N-type semiconductor layer. However, in other embodiments, the polarities of the first-type semiconductor layer 12 and the second-type semiconductor layer 13 may be reversed, while it is not limited thereto. In one embodiment, the type of the active layer 16 disposed between the first-type semiconductor layer 12 and the second-type semiconductor layer 13 may include a multiple quantum well (MQW) active layer, but it is not limited thereto. In one embodiment, the material of the filler layer 14 may include a light-transmitting dielectric material, thereby reducing the loss of light propagating within the filler layer 14. In one embodiment, the light-transmitting dielectric material may include an acrylic material, a siloxane material, a photoresist, a silicone, or other materials having a transmittance greater than 80% or even 90%, or a combination thereof, while it is not limited thereto. The term "material having a transmittance greater than 80% or even 90%" herein means, for example, that when the semiconductor die 11 provides visible light having a wavelength between 400 nanometers (nm) and 700 nm (400 nm ≤ wavelength ≤ 700 nm), the material of the filler layer 14 is selected to have a transmittance greater than 80% or even 90% for the visible light, while it is not limited thereto.

Regarding the reflective layer 15, in one embodiment, the reflective layer 15 may be made of a conductive material. Thus, the reflective layer 15 not only reflects light but also conducts electricity. In one embodiment, the conductive material may include, for example, silver, aluminum, tin, indium or gold, or a combination thereof, but it is not limited thereto.

Regarding the conductive layer 17, in one embodiment, the material of the conductive layer 17 includes a light-transmitting conductive material, so that light may pass through the conductive layer 17. In one embodiment, the light-transmitting conductive material may include, for example, metal oxide, graphene or other suitable transparent conductive materials, or a combination thereof, while it is not limited thereto, wherein the metal oxide may include indium tin oxide, indium zinc oxide, aluminum tin oxide, aluminum zinc oxide, indium germanium zinc oxide or other metal oxides. In another embodiment, the transparent conductive material may also include a thin metal or a metal mesh, for example, a very thin metal layer (for example, a magnesium layer or a silver layer) may be formed, or a metal mesh layer with light-transmitting openings may be formed by screen printing or other patterning processes, so that light may pass through the conductive layer 17, while it is not limited thereto.

Regarding the insulating layer 18, in one embodiment, the material of the insulating layer 18 may include, but not limited to, acrylic, epoxy, silicone, silicon dioxide, silicon oxide, silicon nitride, silicon oxynitride, or other suitable insulating materials, or a combination thereof.

Regarding the pillar 20, in one embodiment, in the Z direction, the pillar 20 may be disposed on one side (for example, the top) of the semiconductor chip 1, while the first electrode 31 and the second electrode 32 may be disposed on the opposite side (for example, the bottom) of the semiconductor chip 1. The density of the pillar 20 may be smaller than or equal to the density of other portions of the semiconductor chip 1 (which will be described in more detail in the following paragraphs). Therefore, when the semiconductor chip 1 is performed with fluid assembly, the orientation of the semiconductor chip 1 in the fluid may be ensured to be correct, for example, with the first electrode 31 and the second electrode 32 facing downward to facilitate assembly, while it is not limited thereto. In one embodiment, the material type of the pillar 20 may be applicable to the material type of the filler layer 14, while it is not limited thereto.

Regarding the first electrode 31 and the second electrode 32, in one embodiment, the material of the first electrode 31 and the second electrode 32 may include gold, tin, indium, copper, or other suitable electrode materials, or a combination thereof, but it is not limited thereto. In one embodiment, the materials of the first electrode 31 and the second electrode 32 may be the same, but may also be different.

It should be noted that, in some embodiments, the semiconductor chip 1 may, for example, have a three-dimensional structure that is wider at the top and narrower at the bottom, or narrower at the top and wider at the bottom. For example, the semiconductor chip 1 as a whole may approximately be a cylinder that is wider at the top and narrower at the bottom, or narrower at the top and wider at the bottom. Therefore, the second electrode 32 may also have, for example, a ring-shaped electrode structure, but it is not limited thereto. In other embodiments, the semiconductor chip 1 may also have a cylinder with the same width at the top and bottom, but it is not limited thereto.

Next, the detailed features of the structure of the semiconductor chip 1 will be described.

In one embodiment, the first-type semiconductor layer 12 and the second-type semiconductor layer 13 may adopt a vertical structure in the Z direction. Furthermore, the first electrode 31 disposed on the second side 10b of the semiconductor unit 10 may be electrically connected to one end of the first-type semiconductor layer 12 also disposed on the second side 10b. For example, the electrical connection may be achieved through a reflective layer 15 disposed between the first electrode 31 and the first-type semiconductor layer 12 in the Z direction. Alternatively, the first electrode 31 may be directly in contact with the first-type semiconductor layer 12 for electrical connection (that is, there is no reflective layer 15 provided between the two), while it is not limited thereto. The second electrode 32 disposed on the second side 10b of the semiconductor unit 10 may be electrically connected to the conductive layer 17 through the reflective layer 15 disposed on the side surface 14c of the filler layer 14. Furthermore, the second electrode 32 may be electrically connected to the second-type semiconductor layer 13 disposed on the first side 10a of the semiconductor unit 10 via the conductive layer 17. In other words, the second electrode 32 and the second-type semiconductor layer 13 may be electrically connected indirectly. Thus, the semiconductor chip 1 of the present disclosure may be formed to be, for example, a vertical embedded flip chip (VEFC), which is advantageous in combining the advantages of both vertical and flip chip technologies, but it is not limited thereto.

In one embodiment, the projection of the side surface 14c of the filler layer 14 on the XZ plane may be an oblique line. For example, the oblique line is not parallel to the X and Z directions. Therefore, the projection of the outline of the filler layer 14 on the XZ plane may approximate a shape that is narrower at the top and wider at the bottom, or wider at the top and narrower at the bottom (for example, a trapezoid or an inverted trapezoid), but it is not limited thereto. In one embodiment, the bottom surface 14b and the side surface 14c of the filler layer 14 may have an angle, hereinafter defined as a first angle θ1. In one embodiment, when the projection of the outline of the filler layer 14 is a shape that is wider at the top and narrower at the bottom, the first angle θ1 may be a right angle or an obtuse angle, for example, between 90 degrees and 150 degrees (90°≦θ1≦150°), or between 90 degrees and 135 degrees (90°≦θ1≦135°), or between 100 degrees and 170 degrees (100°≦θ1≦170°), or between 110 degrees and 150 degrees (110°≦θ1≦150°), or between 120 degrees and 160 degrees (120°≦θ1≦160°), while it is not limited thereto. In addition, in one embodiment, the upper surface 14a and the side surface 14c of the filler layer 14 may have another angle therebetween, which is hereinafter defined as the second angle θ2. In one embodiment, when the projection of the outline of the filler layer 14 is a shape that is wider at the top and narrower at the bottom, the second angle θ2 may be an acute angle, for example, between 10 degrees and 80 degrees (10°≦θ2≦80°), or between 30 degrees and 70 degrees (30°≦θ2≦70°), while it is not limited thereto.

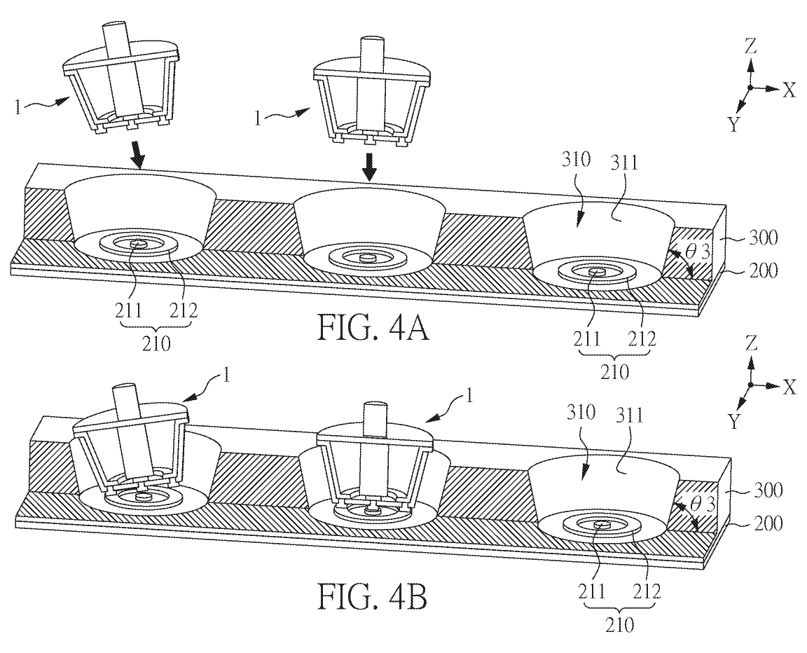

In addition, in one embodiment, in the horizontal direction (for example, the X direction), the width of the upper surface 14a of the filler layer 14 is defined as a first width W1, and the width of the lower surface 14b of the filler layer 14 is defined as a second width W2, wherein the first width W1 and the second width W2 may be different or the same. In one embodiment, the first width W1 may be greater than the second width W2 (W1>W2), but it is not limited thereto. In one embodiment, the width of the semiconductor die 11 in the X direction may be defined as a third width W3, wherein the third width W3 may be smaller than or equal to the first width W1, or smaller than or equal to the second width W2 (W3≦W1 or W3≦W2), but it is not limited thereto. In one embodiment, the first width W1 and the second width W2 may be between 1 and 50 micrometers (μm) (1 μm≦W1≦50 μm, 1 μm≦W2≦50 μm, W1>W2), but it is not limited thereto. In one embodiment, the first width W1 and the second width W2 may be between 10 and 50 micrometers (10 μm ≤ W1 ≤ 50 μm, 10 μm ≤ W2 ≤ 50 μm, W1 > W2), but it is not limited thereto. In one embodiment, the third width W3 may be between 1 and 10 micrometers (1 μm ≤ W3 ≤ 10 μm), but it is not limited thereto. It should be noted that the aforementioned numerical ranges for the filler layer 14 correspond to the semiconductor device 100 of the example in FIG. 4A and FIG. 4B. In practice, these numerical ranges may be adjusted according to different requirements, for example, such that the second width W2 is greater than or equal to the first width W1, but it is not limited thereto.

With the aforementioned features, the side surface 14c of the filler layer 14 may have an angle with respect to the X-direction and the Z-direction, and the shape of the semiconductor chip 1 may also correspond to the shape of the filler layer 14. One of the effects of the shape feature of the filler layer 14 is that, in some cases, such as when performing fluid assembly, the assembly position corresponding to the semiconductor chip 1 (such as a receiving hole 310 of the semiconductor device 100 in FIG. 4A) may have a special shape. If the shape of the semiconductor chip 1 conflicts with the shape of the assembly position, the quality of the fluid assembly may be reduced, such as a decrease in the assembly yield. However, by designing the shape feature of the filler layer 14, the shape of the semiconductor chip 1 may be adjusted to correspond to the shape of the assembly position, thereby improving the quality of the fluid assembly, such as improving or maintaining the assembly yield of the fluid assembly, while it is not limited thereto.

As can be seen, in some embodiments, the shape of the filler layer 14 may be adjusted to the shape of the receiving hole 310 (as shown in FIG. 4A). To achieve this object, the semiconductor unit 10 may be fabricated using a specialized photolithography process. The fabrication process of the semiconductor unit 10 will be described subsequently.

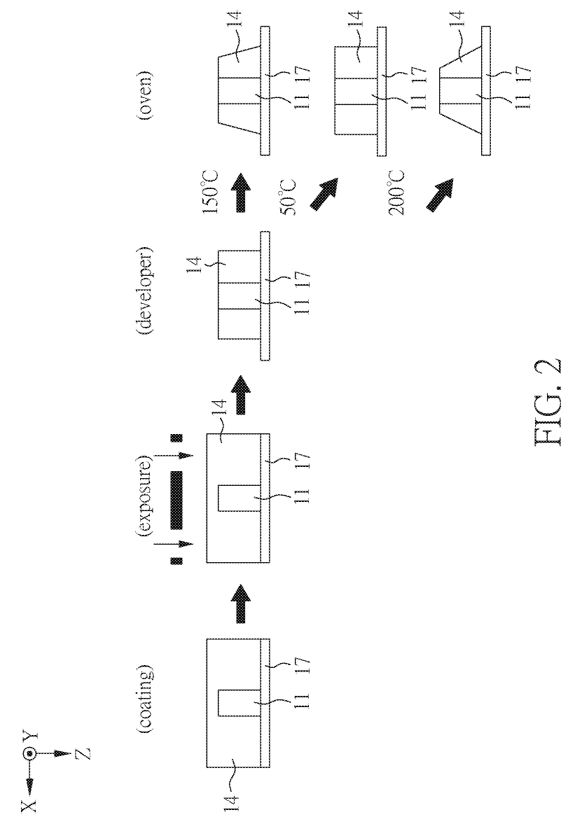

FIG. 2 is a schematic diagram of the manufacturing process of the semiconductor unit 10 according to an embodiment of the present disclosure, and please refer to FIG. 1B for assistance (some component symbols may be seen in FIG. 1B). As shown in FIG. 2, first, a coating step (coating) of the photolithography process may be performed, in which, for example, a filler layer 14 (for example, serving as a photoresist) covers around the semiconductor die 11. Then, an exposure step (exposure) of the photolithography process may be performed, in which, for example, the filler layer 14 is exposed to light to transfer the mask pattern to the filler layer 14. Then, a developing step (developer) of the photolithography process may be performed, in which, for example, using a developer to develop the portion of the filler layer 14 with the mask pattern, and using the developer to dissolve the unnecessary portion of the filler layer 14. Then, a thermal curing step (oven) of the photolithography process is performed, in which different thermal curing temperatures are used to adjust the shape of the filler layer 14 so that the shape of the filler layer 14 is adjusted to correspond to the shape of the receiving hole 310 (as shown in FIG. 4A). In one embodiment, as the thermal curing temperature increases, the first angle θ1 may increase, but it is not limited thereto. In one embodiment, corresponding to the example of the receiving hole 310 in FIG. 4A, the thermal curing temperature may be between 50°C and 200°C (for example, greater than or equal to 50°C and smaller than or equal to 200°C), but it is not limited thereto. Thus, the manufacturing process of the semiconductor unit 10 and the method for adjusting the shape of the filler layer 14 can be understood.

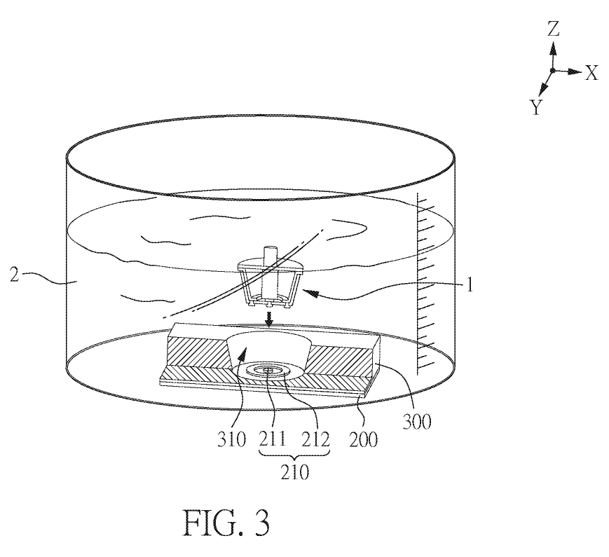

In some embodiments, different densities are set for different portions of the semiconductor chip 1 to facilitate the fluid assembly process, which will be described below. FIG. 3 is a schematic diagram of a semiconductor chip 1 used for fluid assembly according to one embodiment of the present disclosure, and please refer to FIGS. 1A to 2 for assistance. It should be noted that the semiconductor chip 1 in FIG. 3 is presented in the cross-sectional structure of FIG. 1B to enhance the detail, but in practice, it will typically be in the configuration of FIG. 1A.

As shown in FIG. 3, during fluid assembly, the semiconductor chip 1 is placed in a fluid 2 and gradually sinks in the fluid 2 to reach its target position, such as a receiving hole 310 of a unit definition layer 300, and the unit definition layer 300 may be disposed on a substrate 200.

In one embodiment, the density of the semiconductor die 11 may be greater than the density of the filler layer 14. Thus, the semiconductor die 11 disposed in the center of the semiconductor chip 1 have a relatively high density, while the filler layer 14 surrounding the semiconductor die 11 and disposed on the periphery of the semiconductor chip 1 has a relatively low density, so that the central axis of the semiconductor chip 1 may be kept stable in the fluid during the fluid assembly process, thereby preventing the semiconductor chip 1 from tipping over while moving in the fluid.

In one embodiment, the density of the pillar 20 may be substantially equal to the density of the filler layer 14, and the density of the semiconductor die 11 may be greater than the density of the pillar 20 and the density of the filler layer 14. Furthermore, the density of the first electrode 31 may be substantially equal to the density of the second electrode 32, and the density of the first electrode 31 and the density of the second electrode 32 are each greater than the density of the pillar 20 and the filler layer 14. Furthermore, the density of the first electrode 31 and the density of the second electrode 32 are each greater than the density of the semiconductor die 11. Thus, in the Z direction, the first electrode 31 and the second electrode 32 at the bottom of the semiconductor chip 1 have a relatively higher density, the semiconductor die 11 at the center of the semiconductor chip 1 has a relatively lower density, and the pillar 20 at the top of the semiconductor chip 1 has a relatively lower density, so as to facilitate easier movement of the semiconductor chip 1 to a target location during fluid assembly, and facilitate easier bonding of the first electrode 31 and the second electrode 32 to a specific target at the target location, such as the pad 210 within the receiving hole 310.

In one embodiment, the density of the filler layer 14 (or the pillar 20) may be between 0.25 grams per cubic centimeter (g/cm³) and 3 grams per cubic centimeter (0.25 g/cm³≦density of the filler layer 14 (or the pillar 20)≦3 g/cm³), but it is not limited thereto. In one embodiment, the density of the filler layer 14 (or the pillar 20) may be between 1 gram per cubic centimeter and 2 grams per cubic centimeter (1 g/cm³≦density of the filler layer 14 (or the pillar 20)≦2 g/cm³), but it is not limited thereto. In one embodiment, the density of the filler layer 14 (or the pillar 20) may be between 1.25 grams per cubic centimeter and 1.75 grams per cubic centimeter (1.25 g/cm³≦density of the filler layer 14 (or the pillar 20)≦1.75 g/cm³), but it is not limited thereto.

In one embodiment, the density of the semiconductor die 11 may be between 3 grams per cubic centimeter and 8 grams per cubic centimeter (3 g/cm³≦density of semiconductor die 11≦8 g/cm³), but it is not limited thereto. In one embodiment, the density of the semiconductor die 11 may be between 4 grams per cubic centimeter and 7 grams per cubic centimeter (4 g/cm³≦density of semiconductor die 11≦7 g/cm³), but it is not limited thereto. In one embodiment, the density of the semiconductor die 11 may be between 4 grams per cubic centimeter and 6 grams per cubic centimeter (4 g/cm³≦density of semiconductor die 11≦6 g/cm³), but it is not limited thereto. In one embodiment, the density of the semiconductor die 11 may be between 4 grams per cubic centimeter and 5.5 grams per cubic centimeter (4 g/cm³≦density of semiconductor die 11≦5.5 g/cm³), but it is not limited thereto.

In one embodiment, the densities of the first electrode 31 and the second electrode 32 may each be greater than 5 grams per cubic centimeter (5 g/cm³≦density of the first electrode 31 (or the second electrode 32)), but it is not limited thereto. In one embodiment, the densities of the first electrode 31 and the second electrode 32 may each be between 5 grams per cubic centimeter and 25 grams per cubic centimeter (5 g/cm³≦density of the first electrode 31 (or the second electrode 32)≦25 g/cm³), but it is not limited thereto. In one embodiment, the densities of the first electrode 31 and the second electrode 32 may each be between 5 grams per cubic centimeter and 20 grams per cubic centimeter (5 g/cm³≦density of the first electrode 31 (or the second electrode 32)≦20 g/cm³), but it is not limited thereto. In one embodiment, the densities of the first electrode 31 and the second electrode 32 may each be between 6 grams per cubic centimeter and 20 grams per cubic centimeter (6 g/cm³≦density of the first electrode 31 (or the second electrode 32)≦20 g/cm³), but it is not limited thereto. In one embodiment, the densities of the first electrode 31 and the second electrode 32 may each be between 7 grams per cubic centimeter and 20 grams per cubic centimeter (7 g/cm³≦density of the first electrode 31 (or the second electrode 32)≦20 g/cm³), but it is not limited thereto. In one embodiment, the densities of the first electrode 31 and the second electrode 32 may each be between 10 grams per cubic centimeter and 20 grams per cubic centimeter (10 g/cm³≦density of the first electrode 31 (or the second electrode 32)≦20 g/cm³), but it is not limited thereto.

In one embodiment, the density of fluid 2 may be smaller than 1 gram per cubic centimeter (density of fluid <1 g/cm³), but it is not limited thereto. In one embodiment, the density of fluid 2 may be greater than or equal to 0.5 grams per cubic centimeter and smaller than 1 gram per cubic centimeter (0.5 g/cm³≦density of fluid <1 g/cm³), but it is not limited thereto. In one embodiment, the density of fluid 2 may be greater than or equal to 0.6 grams per cubic centimeter and smaller than 1 gram per cubic centimeter (0.6 g/cm³≦density of fluid <1 g/cm³), but it is not limited thereto. In one embodiment, the density of fluid 2 may be greater than or equal to 0.7 grams per cubic centimeter and smaller than 1 gram per cubic centimeter (0.7 g/cm³≦density of fluid <1 g/cm³), but it is not limited thereto.

Accordingly, the density configuration of each portion of the semiconductor chip 1 can be understood.

Next, a semiconductor device 100 formed by fluid assembly of a semiconductor chip 1 will be described. FIG. 4A is a schematic diagram of a semiconductor device 100 (assembly process) according to one embodiment of the present disclosure, and FIG. 4B is a schematic diagram of a semiconductor device 100 (assembly completed) according to another embodiment of the present disclosure, and please refer to FIGS. 1A to 3 for assistance. It should be noted that, to enhance the details, the semiconductor chip 1 in FIGS. 4A and 4B is shown with the cross-sectional structure of FIG. 1B, but in practice, it will typically be in the configuration of FIG. 1A.

As shown in FIGS. 4A and 4B, the semiconductor device 100 may include a substrate 200, a unit definition layer 300, and a semiconductor chip 1. The substrate 200 may have at least one pad 210. In the Z direction, the unit definition layer 300 is arranged on the substrate 200 and includes at least one receiving hole 310, wherein the pad 210 is disposed in the receiving hole 310. For example, when the substrate 200 has a plurality of pads 210 and the unit definition layer 300 has a plurality of receiving holes 310, each receiving hole 310 may be provided with a pad 210, and each receiving hole 310 may be used to receive at least one semiconductor chip 1, but it is not limited thereto. In addition, the details of the semiconductor chip 1 may refer to the description of the aforementioned embodiment, and thus a detailed description is deemed unnecessary. It should be noted that the pillar 20 on the semiconductor chip 1 in the semiconductor device 100 after assembly may be removed.

In one embodiment, the unit definition layer 300 may be, for example, a dielectric layer, and the material type thereof may include organic material, inorganic material, glass or other suitable materials, or a combination thereof, but it is not limited thereto.

As shown in FIG. 4A, in one embodiment, each receiving hole 310 may be used to receive a semiconductor chip 1. Each semiconductor chip 1 may be inserted into the receiving hole 310 through fluid assembly, and an electrode 30 (for example, a first electrode 31 and a second electrode 32) of the semiconductor chip 1 may be bonded to the pad 210 to achieve electrical connection between the semiconductor chip 1 and the substrate 200. Furthermore, as shown in FIG. 4B, in one embodiment, after the electrode 30 of the semiconductor chip 1 is bonded to the pad 210 of the substrate 200, the pillar 20 of the semiconductor chip 1 may be removed, but it is not limited thereto.

In one embodiment, each receiving hole 310 may have a side wall 311, and the angle between the projection of the side wall 311 on the XZ plane and the horizontal direction (for example, the X direction) may be defined as a third angle θ3. In one embodiment, the third angle θ3 may be between 10 degrees and 90 degrees (10°≦θ3≦90°), or between 10 degrees and 80 degrees (10°≦θ3≦80°), or between 30 degrees and 70 degrees (30°≦θ3≦70°), while it is not limited thereto. In one embodiment, the third angle θ3 may be complementary to the first angle θ1, but is not limited thereto. Depending on the third angle θ3, the receiving hole 310 may have different shapes, that is, the shape of the receiving hole 310 may be defined, for example, by the third angle θ3. Thus, when the shape of the semiconductor chip 1 and the receiving hole 310 are compatible (for example, both are wider at the top and narrower at the bottom), the semiconductor chip 1 may be more easily inserted into the receiving hole 310 via fluid assembly, thereby improving the fluid assembly insertion rate. It should be noted that the numerical range of the third angle θ3 described above is merely an example and may be adjusted as needed.

In one embodiment, the pad 210 may include a first pad 211 and a second pad 212. The second pad 212 may surround the first pad 211, wherein the first pad 211 may be disposed in the middle of the receiving hole 310, but it is not limited thereto. The first pad 211 may be configured to be electrically connected to the first electrode 31 of the semiconductor chip 1, and the second pad 212 may be configured to be electrically connected to the second electrode 32 of the semiconductor chip 1, but it is not limited thereto. In one embodiment, the second electrode 32 and the second pad 212 may each be, for example, a ring-shaped structure, but it is not limited thereto.

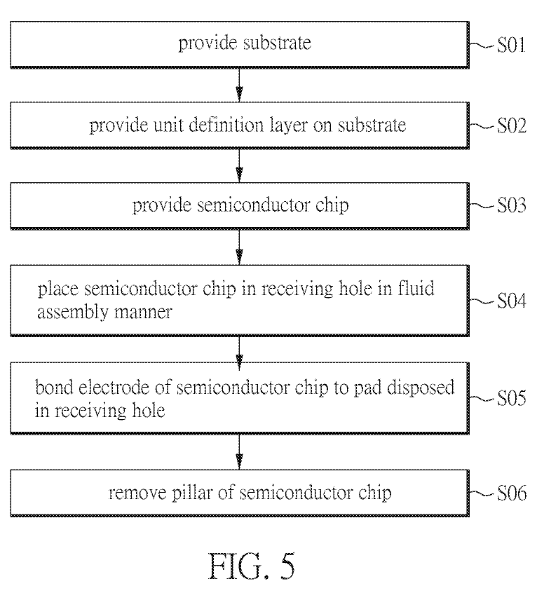

Next, a method for manufacturing the semiconductor device 100 will be described. FIG. 5 is a flowchart illustrating the steps of the method for manufacturing the semiconductor device 100 according to an embodiment of the present disclosure, and please refer to FIGS. 1A to 4 for assistance. As shown in FIG. 5, first, step S01 is performed to provide a substrate 200. Then, step S02 is performed to provide a unit definition layer 300 including a receiving hole 310 on the substrate 200, wherein the pad 210 of the substrate 200 is disposed in the receiving hole 310 of the unit definition layer 300. Then, step S03 is performed to provide a semiconductor chip 1. Then, step S04 is performed to place the semiconductor chip 1 in the receiving hole 310 in a fluid assembly manner. Then, step S05 is performed to bond the electrode 30 of the semiconductor chip 1 to the pad 210 disposed in the receiving hole 310. Then, step S06 is performed to remove the pillar 20 of the semiconductor chip 1.

Regarding steps S01 and S02, in one embodiment, the substrate 200 may have a plurality of pads 210, wherein when the unit definition layer 300 is disposed on the substrate 200, the position of each receiving hole 310 may correspond to the position of a pad 210 on the substrate 200. Therefore, after the unit definition layer 300 is disposed on the substrate 200, each receiving hole 310 may have a pad 210, but it is not limited thereto.

Regarding step S03, the components and detailed features of the semiconductor chip 1 may be applicable to the description of the previous embodiment, and thus a detailed description is deemed unnecessary.

Regarding steps S04 to S06, due to the shape characteristics of the semiconductor chip 1 and the density configuration of various portions, the semiconductor chip 1 may have good directionality in the fluid, suitable for being arranged in the receiving hole 310 in a fluid assembly manner. Each receiving hole 310 may accommodate at least one semiconductor chip 1, but it is not limited thereto. In addition, since the direction of the semiconductor chip 1 in the fluid may be kept stable, it is also beneficial to the bonding of the electrode 30 of the semiconductor chip 1 and the pad 210 in the receiving hole 310. In addition, after the semiconductor chip 1 is successfully bonded to the substrate 200, the pillar 20 may be removed, and the semiconductor device 100 may be formed.

It should be noted that the order of the above steps may be adjusted as needed as long as it is reasonable and feasible, and additional steps may be added or steps may be reduced as needed, and the present disclosure is not limited thereto.

Accordingly, the method for manufacturing the semiconductor device 100 can be understood.

It can be seen that the semiconductor chip 1 provided in the present disclosure has a special structural feature, which is conducive to being arranged on the substrate 200 through fluid assembly to form the semiconductor device 100.

In one embodiment, the present disclosure may determine whether a product in contention falls within the protection scope of the present disclosure at least by the presence or absence of components, component configurations, mechanism observation and/or operating modes of the product, while it is not limited thereto. Alternatively, the present disclosure may determine whether a product in contention falls within the protection scope of the present disclosure by the manufacturing method of the product in contention, while it is not limited thereto.

The details or features of the various embodiments of the present disclosure may be mixed and matched as long as they do not violate the spirit of the invention or conflict with each other.

The aforementioned specific embodiments should be construed as merely illustrative, and not limiting the rest of the present disclosure in any way.

1. A semiconductor chip, comprising:
a semiconductor unit including a semiconductor die and a filler layer, wherein the filler layer surrounds the semiconductor die, and the semiconductor die includes a first-type semiconductor layer and a second-type semiconductor layer;
a pillar disposed on a first side of the semiconductor unit;
a first electrode electrically connected to the first-type semiconductor layer; and
a second electrode electrically connected to the second-type semiconductor layer,
wherein the first electrode and the second electrode are disposed on a second side of the semiconductor unit, and a center of gravity of the semiconductor chip is closer to the second side of the semiconductor unit than to the first side of the semiconductor unit.

2. The semiconductor chip as claimed in claim 1, further comprising a reflective layer disposed on a side surface of the filler layer.

3. The semiconductor chip as claimed in claim 2, wherein the reflective layer is electrically connected to the second electrode.

4. The semiconductor chip as claimed in claim 1, wherein the semiconductor die further includes an active layer disposed between the first-type semiconductor layer and the second-type semiconductor layer.

5. The semiconductor chip as claimed in claim 1, wherein a density of the first electrode and a density of the second electrode are each greater than a density of the pillar.

6. The semiconductor chip as claimed in claim 1, wherein a density of the semiconductor die is greater than a density of the filler layer.

7. The semiconductor chip as claimed in claim 1, wherein a width of an upper surface of the filler layer is greater than a width of a lower surface of the filler layer.

8. The semiconductor chip as claimed in claim 1, wherein a density of the semiconductor die is between 4 grams per cubic centimeter and 7 grams per cubic centimeter.

9. The semiconductor chip as claimed in claim 1, wherein a density of the first electrode and a density of the second electrode are each between 7 grams per cubic centimeter and 20 grams per cubic centimeter.

10. The semiconductor chip as claimed in claim 1, wherein a density of the filler layer is between 1 gram per cubic centimeter and 2 grams per cubic centimeter.

11. The semiconductor chip as claimed in claim 1, wherein a density of the first electrode and a density of the second electrode are each greater than a density of the semiconductor die, and a density of the semiconductor die is greater than a density of the pillar.

12. The semiconductor chip as claimed in claim 11, wherein the density of the pillar is the same as a density of the filler layer.

13. The semiconductor chip as claimed in claim 1, wherein the second electrode is electrically connected to the second-type semiconductor layer via a reflective layer and a conductive layer.

14. The semiconductor chip as claimed in claim 1, wherein the filler layer has a lower surface and a side surface, an angle is formed between the lower surface and the side surface, and the angle is a right angle or an obtuse angle.

15. The semiconductor chip as claimed in claim 1, wherein the filler layer has an upper surface and a lower surface, the upper surface has a first width, the lower surface has a second width, and the first width and the second width are different.

16. The semiconductor chip as claimed in claim 15, wherein the filler layer has an upper surface and a lower surface, the upper surface has a first width, the lower surface has a second width, and the first width and the second width are the same.

17. A semiconductor device, comprising:
a substrate including a pad;
a unit definition layer disposed on the substrate and provided with a receiving hole, wherein the pad is disposed in the receiving hole; and
a semiconductor chip disposed in the receiving hole and bonded to the pad, comprising:
a semiconductor unit including a semiconductor die and a filler layer, wherein the filler layer surrounds the semiconductor die, and the semiconductor die includes a first-type semiconductor layer and a second-type semiconductor layer;
a first electrode electrically connected to the first-type semiconductor layer; and
a second electrode electrically connected to the second-type semiconductor layer,
wherein the semiconductor unit has a first side and a second side, the first electrode and the second electrode are disposed on the second side of the semiconductor unit, and a center of gravity of the semiconductor chip is closer to the second side of the semiconductor unit than to the first side of the semiconductor unit.

18. A method for manufacturing a semiconductor device, comprising the steps of:
providing a unit definition layer, wherein the unit definition layer includes a receiving hole;
providing a semiconductor chip, wherein the semiconductor chip includes:
a semiconductor unit including a semiconductor die and a filler layer surrounding the semiconductor die;
a pillar disposed on a first side of the semiconductor unit; and
an electrode electrically connected to the semiconductor unit and disposed on a second side of the semiconductor unit,
wherein a center of gravity of the semiconductor chip is closer to the second side of the semiconductor unit than to the first side of the semiconductor unit; and
disposing the semiconductor chip in the receiving hole in a fluid assembly manner.

19. The method as claimed in claim 18, further comprising the step of removing the pillar.

20. The method as claimed in claim 18, wherein the semiconductor device further includes a substrate having a pad disposed in the receiving hole, further comprising the step of bonding the electrode of the semiconductor chip to the pad.
